(19) United States
(12) Patent Application Publication
(10) Pub. No.: US 2014/0008313 A1
(43) Pub. Date: Jan. 9, 2014

(54) RACK FOR ELECTRONIC APPARATUS

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventor: CHANG-GUI CHEN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/866,384

(22) Filed: Apr. 19, 2013

(30) Foreign Application Priority Data
Jul. 9, 2012 (CN) 201210235321.0

(51) Int. Cl. H05K 7/18

(52) U.S. Cl. CPC H05K 7/18
USPC 211/26

(57) ABSTRACT

A rack includes a rack body, an installation member attached to the rack body, at least one latch member secured to the installation member, and a supporting assembly. The supporting assembly is engaged between the installation member and the at least one latch member. The supporting assembly is retractable relative to the rack body between a first position and a second position, in the first position, the supporting assembly is extended out from the rack body, and an end of the supporting assembly away from the rack body supports the rack body; in the second position, the supporting assembly is retracted in the rack body.

### BACKGROUND

1. Technical Field

The present disclosure relates to racks, and particularly to a rack for an electronic apparatus.

2. Description of Related Art

Certain computer systems, such as computer network systems, are made up of many separate computer units or servers, which can be positioned and stacked in a rack. The various computer servers in the system are electrically interconnected to each other and provide various functions, such as storage, communications, calculations, and others. The rack only includes a plurality of support columns located on a bottom portion of the rack to support the rack. However, if the rack is too high, the rack can be unstable when it is vibrated.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric and exploded view of a rack in accordance with one embodiment.

FIG. 2 is isometric view of a supporting assembly of FIG, 1.

FIG. 3 is an assembled view of the rack of FIG. 1, and the supporting assembly is located in the first position.

FIG. 4 is another assembled view of the rack of FIG. 1, and the supporting assembly is located in the second position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

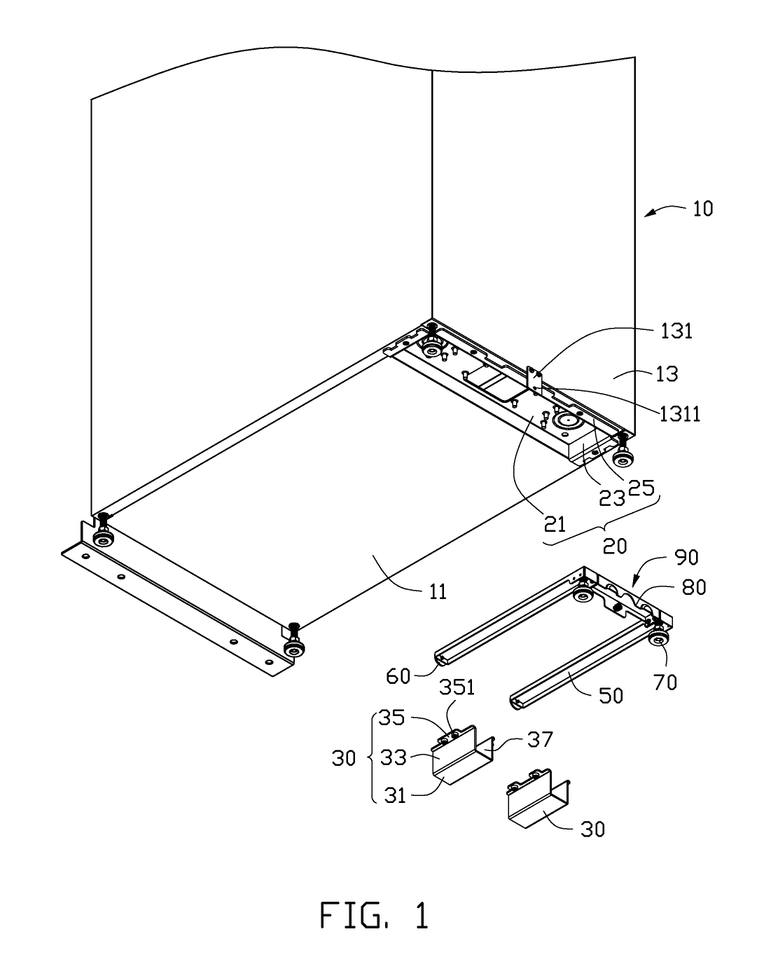

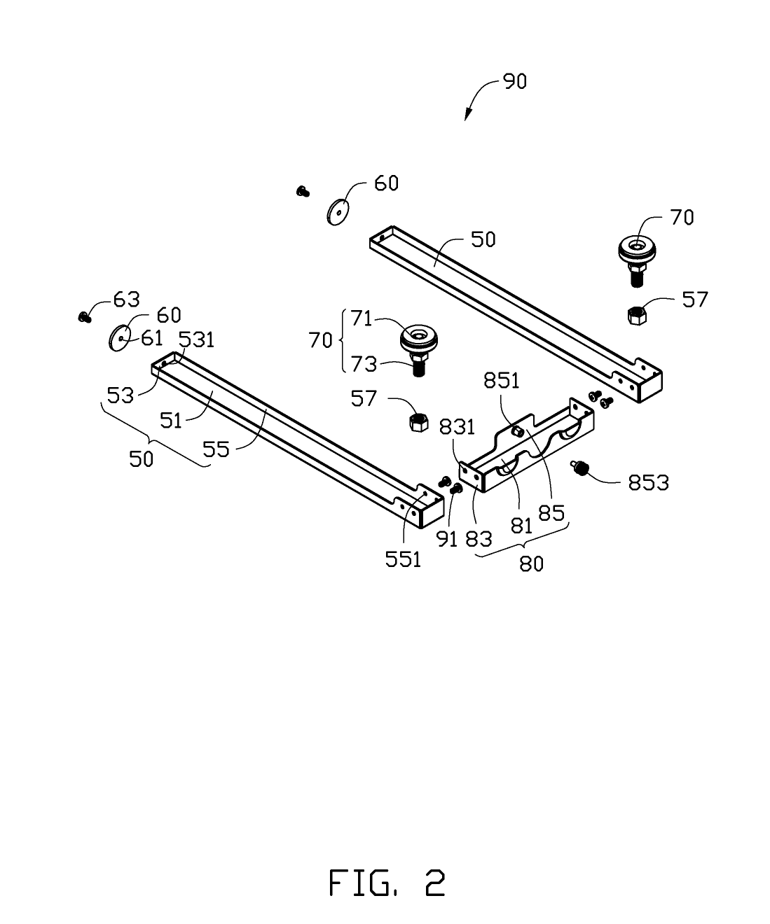

FIGS. 1 and 2 illustrate a rack in accordance with an embodiment. The rack includes a rack body 10, a latch assembly 40 secured to the rack body 10, and a supporting assembly 90. In one embodiment, the rack is configured to receive electronic devices therein, such as servers.

The rack body 10 includes a bottom frame 11 and a sidewall 13. In one embodiment, the rack body 10 is substantially cubic. The sidewall 13 is located on one side of the bottom frame 11. A stopping piece 131, secured to the sidewall 13, is adjacent to the bottom frame 11. A stopping hole 1311 is defined in the stopping piece 131, for securing the supporting assembly 90.

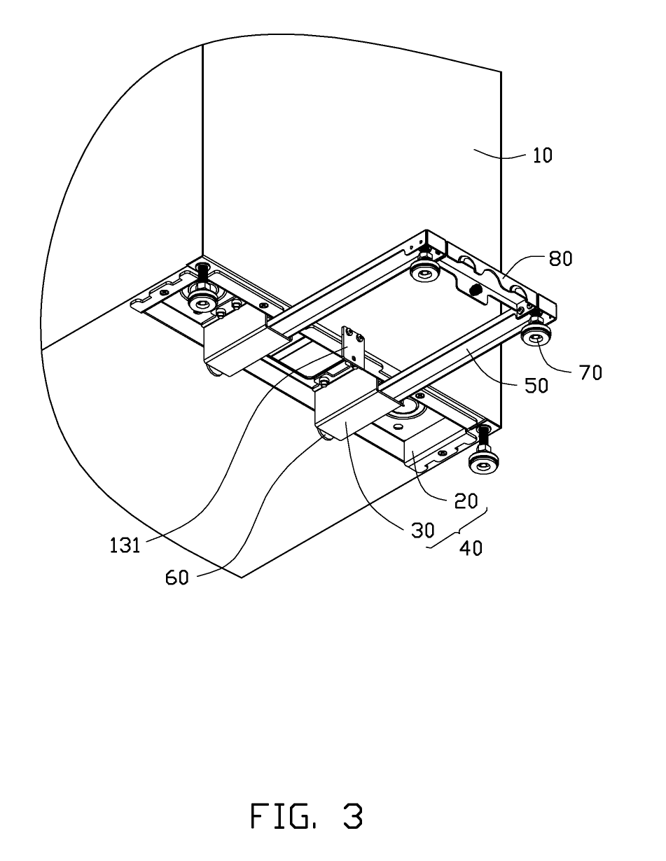

The latch assembly 40 (show in FIG. 3) includes an installation member 20 and two latch members 30. The installation member 20 includes an installation plate 21, two fixing plates 23 and a securing plate 25. The two fixing plates 23 and the securing plate 25 are located on three sides of the installation plate 21 and secured to the bottom frame 11, to secure the latch assembly 40 to the rack body 10. The two latch members 30 are fixed on the installation plate 21.

Each of the two latch members 30 includes a resisting piece 31, two clipping pieces 33, and two fixing tabs 35. The resisting piece 31, the two clipping pieces 33, and the two fixing tabs 35 cooperatively define a sliding cavity 37, for receiving the supporting assembly 90. The two clipping pieces 33 extend upwards from two opposite sides of the resisting piece 31. The two clipping pieces 33 are substantially parallel with each other and perpendicular to the resisting piece 31. The two fixing tabs 35 extend from the two clipping pieces 33, respectively. Each of the two fixing tabs 35 defines two securing holes 351.

Referring to FIG. 2, the supporting assembly 90 includes two sliding levers 50, two blocking pieces 60, and two feet 70, and a connecting member 80. Each of the two sliding levers 50 includes a sliding plate 51, a mounting tab 53, and a flange 55. The mounting tab 53 and the flange 55 extend from two adjacent sides of the sliding plate 51, respectively. The mounting tab 53 defines a mounting hole 531, and each of the two blocking pieces 60 defines a through hole 61, corresponding to the mounting hole 531. The fixing member 63 is screwed into the through hole 61, of each of the two blocking pieces 60 and the mounting hole 531 of each mounting tab 53, to secure the two blocking pieces 60 to the two sliding levers 50. The flange 55 defines two locking holes 551 in a corner of the flange 55. Each of two screws 57 is attached to each sliding plate 51 and adjacent to the two locking holes 551 of each flange 55.

The connecting member 80 includes a connecting plate 81, two connecting tabs 83, and a blocking tab 85. The two connecting tabs 83 extend from two opposite sides of the connecting plate 81. Two connecting holes 831 are defined in each of the two connecting tabs 83, corresponding to two locking holes 551 of each flange 55. The blocking tab 85 extends from one side of the connecting plate 81 and connected to the two connecting tabs 83. A blocking hole 851 is defined in the blocking tab 85, corresponding to the stopping hole 1311.

Each of the two feet 70 can stand on ground (not shown), to support the rack body 10, and includes a supporting portion 71 and a threaded post 73 extending from the supporting portion 71. The supporting portion 71 abuts the ground when the supporting assembly 90 is used to support the rack body 10. Each threaded post 73 is rotatably engaged in each screw 57, to adjust a height between each supporting portion 71 and each sliding plate 51.

Referring to FIG. 3, in assembly, two locking members 91 extend through the two connecting holes 831 and the two locking holes 551, to secure the connecting member 80 between the two sliding levers 50. The two feet 70 are rotatably secured to the two screws 57. Each of the two sliding levers 50 of the supporting assembly 90 extends through the sliding cavity 37 of each of the two latch members 30 and is engaged between the securing plate 25 and the resisting piece 31 of the two latch members 30. Each of the two blocking pieces 60 is secured to each of the two sliding levers 50 and capable of abutting each of the two latch members 30.

The connecting member 80 is pulled out along a first direction to slide the two sliding levers 50, until the supporting assembly 90 is moved to a first position, where each of the two blocking pieces 60 is engaged with each of the two latch members 30, and the connecting member 80 is disengaged from the rack body 10. Each of the two feet 70 is rotated until the supporting portion 71 abuts the ground to support the rack body 10, for preventing the rack body 10 from toppling.

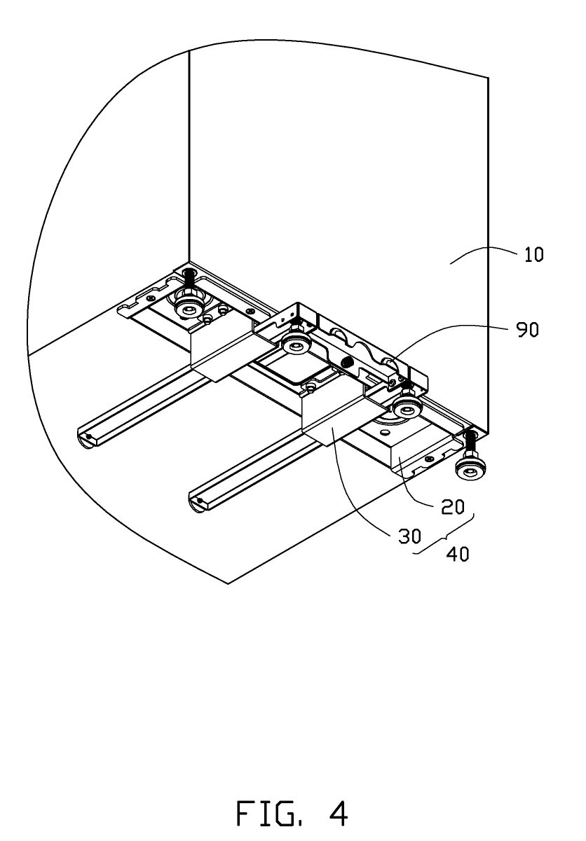

Referring to FIG. 4, when the supporting assembly 90 is needed to be retracted, each of the two feet 70 is rotated until the supporting portion 71 lift away from the ground. The connecting member 80 is pushed in along a second direction opposite to the first direction. The supporting assembly 90 is located in a second position, where each of the two blocking pieces 60 is disengaged from each of the two latch members 30, and the blocking tab 85 abuts the stopping piece 131 to align the stopping hole 1311 with the blocking hole 851. For retaining the retracted supporting assembly 90, a thumb screw 853 can be used to secure the supporting assembly 90 to the rack body 10 through extending into the blocking hole 851 and the stopping hole 1311.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A rack, comprising:
a rack body;
an installation member attached to the rack body;
at least one latch member secured to the installation member; and
a supporting assembly engaged between the installation member and the at least one latch member,
wherein the supporting assembly is retractable relative to the rack body between a first position and a second position; in the first position, the supporting assembly is extended out from the rack body, and an end of the supporting assembly away from the rack body supports the rack body; and in the second position, the supporting assembly is retracted in the rack body.

2. The rack of claim 1, wherein the at least one latch member comprises two latch members, the supporting assembly comprises two blocking pieces and a connecting member, when the supporting assembly is located in the first position, each of the two blocking pieces is engaged with each of the two latch members, and the connecting member is disengaged from the rack body; and when the supporting assembly is located in the second position, each of the two blocking pieces is disengaged from each of the two latch members, and the connecting member is engaged with the rack body.

3. The rack of claim 2, wherein the supporting assembly further comprises two sliding levers, each of the two blocking pieces is located on a first end of each of the two sliding levers, and the connecting member is connected to a second end of the two sliding levers.

4. The rack of claim 2, wherein the connecting member comprises a blocking tab, a stopping piece is located on the rack body, when the supporting assembly is located in the first position, the blocking tab is engaged with the stopping piece; and when the supporting assembly is located in the second position, the blocking tab is disengaged from the stopping piece.

5. The rack of claim 3, wherein the connecting member further comprises two connecting tabs, each of the two sliding levers comprises a flange, and each of the two connecting tabs is secured to the flange of each of the two sliding levers.

6. The rack of claim 3, wherein each of the two sliding levers comprises a sliding plate, each of the two latch members defines a sliding cavity, the installation member comprises a securing plate secured to the rack body, each sliding plate is engaged in each sliding cavity, and the securing plate abuts each sliding plate, to prevent each sliding plate disengagement from each sliding cavity.

7. The rack of claim 6, wherein each of the two latch members comprises a resisting piece and two clipping pieces; and the resisting piece and the two clipping pieces cooperatively define the sliding cavity.

8. The rack of claim 6, wherein the supporting assembly further comprises two feet, each of the two feet is rotatably secured to the sliding plate of each of the two sliding levers.

9. The rack of claim 8, wherein the supporting assembly further comprises two screws, each of the two screws is secured to the sliding plate of each of the two sliding levers, and each of the two feet is engaged in each of the two screws.

10. A rack, comprising:
a rack body;
a latch assembly attached to the rack body; and
a supporting assembly engaged with the latch assembly,
wherein the supporting assembly is retractable relative to the rack body between a first position and a second position; in the first position, the supporting assembly is extended out from the rack body, and an end of the supporting assembly away from the rack body supports the rack body; and in the second position, the supporting assembly is retracted in the rack body.

11. The rack of claim 10, wherein the latch assembly comprises an installation member and two latch members, each of the two latch members is secured to the installation member, and the supporting assembly is engaged between the two latch members and the installation member.

12. The rack of claim 11, wherein the supporting assembly comprises two blocking pieces and a connecting member, when the supporting assembly is located in the first position, each of the two blocking pieces is engaged with each of the two latch members, and the connecting member is disengaged from the rack body; and when the supporting assembly is located in the second position, each of the two blocking pieces is disengaged from each of the two latch members, and the connecting member is engaged with the rack body.

13. The rack of claim 12, wherein the supporting assembly further comprises two sliding levers, each of the two blocking pieces is located on a first end of each of the two sliding levers, and the connecting member is connected to a second end of the two sliding levers.

14. The rack of claim 12, wherein the connecting member comprises a blocking tab, a stopping piece is located on the rack body, when the supporting assembly is located in the first position, the blocking tab is engaged with the stopping piece; and when the supporting assembly is located in the second position, the blocking tab is disengaged from the stopping piece.

15. The rack of claim 13, wherein the connecting member further comprises two connecting tabs, each of the two sliding levers comprises a flange, and each of the two connecting tabs is secured to the flange of each of the two sliding levers.

16. The rack of claim 13, wherein each of the two sliding levers comprise a sliding plate, each of the two latch members defines a sliding cavity, the installation member comprises a securing plate secured to the rack body, each sliding plate is engaged in each sliding cavity, and the securing plate abuts each sliding plate, to prevent each sliding plate from disengagement from the sliding cavity.

17. The rack of claim 16, wherein each of the two latch members comprises a resisting piece and two clipping pieces, and the resisting piece and the two clipping pieces cooperatively define the sliding cavity.

18. The rack of claim 16, wherein the supporting assembly further comprises two feet, and each of the two feet is rotatably secured to the sliding plate of each of the two sliding levers.

19. The rack of claim 18, wherein the supporting assembly further comprises two screws, each of the two screws is secured to the sliding plate of each of the two sliding levers, and each of the two feet is engaged in each of the two screws.
